(19) United States
(12) Patent Application Publication
(10) Pub. No.: US 2026/0214752 A1
(43) Pub. Date: Jul. 23, 2026

(54) LIGHT SOURCE APPARATUS

(71) Applicant: Lasertec Corporation, Yokohama (JP)

(72) Inventors: Junya KAWAGUCHI, Yokohama (JP); Takahide TAKAMATSU, Yokohama (JP); Masayasu NISHIZAWA, Yokohama (JP); Masaki INOUE, Yokohama (JP)

(21) Appl. No.: 19/456,637

(22) Filed: Jan. 22, 2026

(30) Foreign Application Priority Data
Jan. 23, 2025 (JP) 2025-010030

(51) Int. Cl. H05B 1/02; H05B 7/02

(52) U.S. Cl. CPC H05B 1/0244; H05B 7/02

(57) ABSTRACT

A light source apparatus capable of reducing deformation of a target holding portion is provided. A light source apparatus according to the present disclosure includes a target holding portion including a cylindrical portion in a cylindrical shape, and a holding surface that holds a target member, the target holding portion holding the target member on the holding surface that rotates around a rotational axis, and a temperature adjusting unit configured to adjust a temperature of the cylindrical portion, the temperature adjusting unit includes an upstanding wall portion arranged to face an outer peripheral surface of the cylindrical portion, and the upstanding wall portion faces at least part of the outer peripheral surface of the cylindrical portion.

### INCORPORATION BY REFERENCE

This application is based upon and claims the benefit of priority from Japanese patent application No. 2025-010030, filed on Jan. 23, 2025, the disclosure of which is incorporated herein in its entirety by reference for all purposes.

### BACKGROUND

The present disclosure relates to a light source apparatus.

Japanese Unexamined Patent Application Publication No. 2022-168463 discloses a light source apparatus that holds a liquid target member on an inner peripheral surface of a crucible rotating around a rotational axis by centrifugal force and extracts illumination light by irradiating the held target member with excitation light.

### SUMMARY

In a light source apparatus, in a case where a target member for generating light is held in a target holding portion such as a crucible, if a temperature of the target holding portion is not appropriately adjusted, there is a possibility that the target holding portion may deform due to temperature increase when light is generated. Further, if the target holding portion rotates around a rotational axis, there is a possibility that the target holding portion may deform due to centrifugal force. If the target holding portion deforms in this manner, a position irradiated with the excitation light is displaced, and an optical path of the extracted light is displaced. To stably extract light from the light source apparatus, it is desired to reduce deformation of the target holding portion.

The present disclosure has been made to solve such a problem, and an object of the present disclosure is to provide a light source apparatus capable of reducing deformation of a target holding portion.

A light source apparatus according to the present disclosure includes a target holding portion including a cylindrical portion in a cylindrical shape, and a holding surface that holds a target member, the target holding portion holding the target member on the holding surface that rotates around a rotational axis, and a temperature adjusting unit configured to adjust a temperature of the cylindrical portion, and the temperature adjusting unit includes an upstanding wall portion arranged to face an outer peripheral surface of the cylindrical portion, and the upstanding wall portion faces at least part of the outer peripheral surface of the cylindrical portion.

In the above-described light source apparatus, the cylindrical portion may include a first cylinder end portion that is an end portion on one side in a direction of the rotational axis, and a second cylinder end portion that is an end portion on the other side, the upstanding wall portion may include a first upstanding wall end portion that is an end portion on the one side in the direction of the rotational axis, and a second upstanding wall end portion that is an end portion on the other side, the upstanding wall portion may face the outer peripheral surface of the cylindrical portion via a gap, and the first upstanding wall portion may be located on the one side relative to the second cylinder end portion, and may be located on the other side relative to the first cylinder end portion.

In the above-described light source apparatus, the upstanding wall portion may intersect with a vertical line that is orthogonal to the rotational axis and passes through a point at which plasma formed from the target member is formed.

In the above-described light source apparatus, the upstanding wall portion may be formed in an annular shape over the entire circumference along a rotation direction of the rotational axis.

In the above-described light source apparatus, the temperature adjusting unit may plurally include the upstanding wall portion as a plurality of upstanding wall portions, and the plurality of upstanding wall portions may be arranged in an annular shape along a rotation direction of the rotational axis.

The above-described light source apparatus may include a cover that covers at least part on the one side in the direction of the rotational axis, of the target holding portion, and an interval between the cover and the cylindrical portion may be narrower than an interval between the cover and the upstanding wall portion.

In the above-described light source apparatus, the target holding portion may further include a flange portion arranged on the one side of the cylindrical portion, and the flange portion may include a portion that covers at least part of the first upstanding wall end portion.

The above-described light source apparatus may further include an introduction unit that introduces gas discharged from between the cylindrical portion and the first upstanding wall end portion.

In the above-described light source apparatus, at least one of the cylindrical portion and the upstanding wall portion may be coated with a material having a predetermined radiation factor.

In the above-described light source apparatus, the predetermined radiation factor may be substantially the same as a radiation factor of the target member.

In the above-described light source apparatus, the target holding portion may further include a bottom portion arranged to close the other side in the direction of the rotational axis, of the cylindrical portion, and the one side in the direction of the rotational axis, of the cylindrical portion, may be open, and a gap between the cylindrical portion and the upstanding wall portion may include a portion that becomes wider as it approaches the one side.

In the above-described light source apparatus, an upstanding wall facing surface facing the cylindrical portion, of the upstanding wall portion, may include a portion that is inclined in a direction farther away from the cylindrical portion as it approaches the one side.

In the above-described light source apparatus, a cylinder facing surface facing the upstanding wall portion, of the cylindrical portion, may include a portion that is inclined in a direction farther away from the upstanding wall portion as it approaches the one side.

In the above-described light source apparatus, the target holding portion may further include a bottom portion that closes the other side in the direction of the rotational axis, of the cylindrical portion, the one side in the direction of the rotational axis, of the cylindrical portion, may be open, and the bottom portion may include a portion having a thickness that becomes thicker in the direction of the rotational axis toward the rotational axis.

In the above-described light source apparatus, the thickness may become gradually thicker toward the rotational axis.

In the above-described light source apparatus, the holding surface may include an inner peripheral surface of the cylindrical portion, and the upstanding wall portion may include a cooling unit that cools the cylindrical portion.

In the above-described light source apparatus, the holding surface may include the outer peripheral surface of the cylindrical portion, and the upstanding wall portion may include a cooling unit that cools the cylindrical portion.

According to the present disclosure, it is possible to reduce deformation of the target holding portion.

The above and other objects, features and advantages of the present disclosure will become more fully understood from the detailed description given hereinbelow and the accompanying drawings.

### BRIEF DESCRIPTION OF DRAWINGS

FIG. 1 is a cross-sectional view illustrating a light source apparatus according to outline of a first embodiment;

FIG. 2 is a cross-sectional view illustrating the light source apparatus according to the outline of the first embodiment;

FIG. 3A is a cross-sectional view illustrating the light source apparatus according to the first embodiment;

FIG. 3B is a cross-sectional views illustrating holding surfaces according to modifications;

FIG. 3C is a cross-sectional views illustrating holding surfaces according to modifications;

FIG. 4 is a cross-sectional view illustrating a target holding portion and an upstanding wall portion in the light source apparatus according to the first embodiment;

FIG. 5 is a cross-sectional view illustrating the target holding portion and the upstanding wall portion in the light source apparatus according to the first embodiment;

FIG. 6 is a cross-sectional view illustrating a light source apparatus according to a modification of the first embodiment;

FIG. 7 is a cross-sectional view illustrating a light source apparatus according to outline of a second embodiment;

FIG. 8 is a cross-sectional view illustrating the light source apparatus according to the outline of the second embodiment;

FIG. 9 is a cross-sectional view illustrating the light source apparatus according to the second embodiment;

FIG. 10 is a cross-sectional view illustrating a light source apparatus according to a modification of the second embodiment;

FIG. 11 is a cross-sectional view illustrating a light source apparatus according to a modification of the second embodiment; and

FIG. 12 is a cross-sectional view illustrating a light source apparatus according to a modification of the second embodiment.

### DESCRIPTION OF EMBODIMENTS

A specific configuration of the present embodiment will be described below with reference to the drawings. The following description indicates embodiments of the present disclosure, and the scope of the present disclosure is not limited to the following embodiments. In the following description, components denoted by the same reference numerals indicate substantially similar content.

A light source apparatus according to an embodiment will be described. The light source apparatus of the present embodiment generates light such as illumination light and exposure light to be used in an optical apparatus such as an inspection apparatus, a review apparatus, and an exposure apparatus. The light source apparatus may be provided integrally with the optical apparatus or may be arranged in the vicinity of the optical apparatus as an apparatus separate from the optical apparatus. In a case where the optical apparatus is an inspection apparatus or a review apparatus, the light source apparatus generates illumination light for illuminating an object to be inspected or an object to be observed in the inspection apparatus or the review apparatus. Further, in a case where the optical apparatus is an exposure apparatus, the light source apparatus generates exposure light for exposing an object to be exposed in the exposure apparatus.

The light source apparatus generates light such as illumination light and exposure light by irradiating a target member held by a target holding portion with excitation light. In first and second embodiments described below, an example where a liquid target member is held in the target holding portion including a container such as a crucible, and an example where a solidified target member is held in the target holding portion including a container such as a drum will be described as an example of the light source apparatus. Note that the light source apparatus is not limited to an apparatus using the liquid target member or the solidified target member and may be an apparatus using a target member in a tape shape or an apparatus using a target member that is dropped or ejected in a droplet shape.

### Outline of First Embodiment

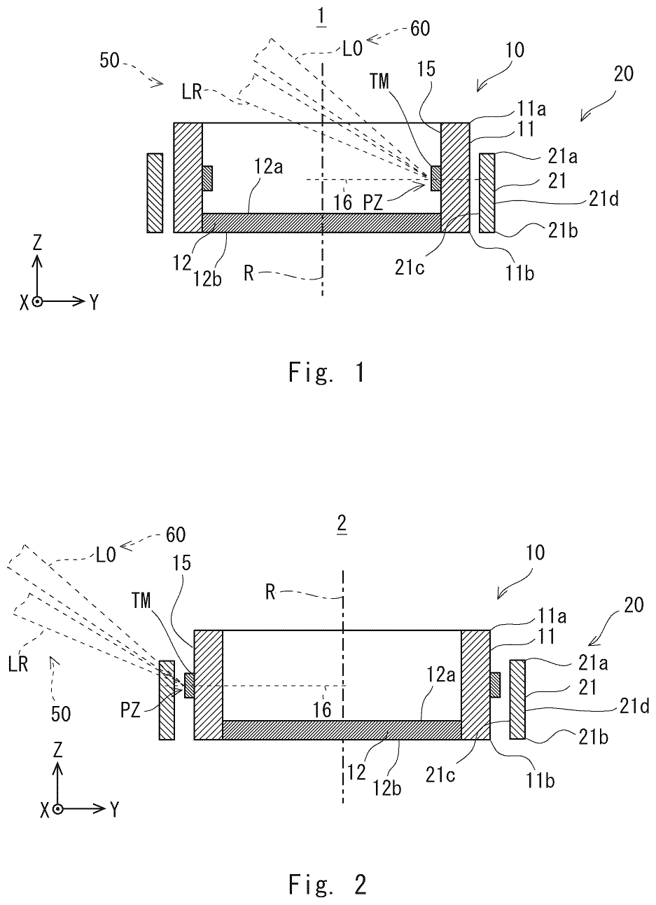

FIG. 1 and FIG. 2 are cross-sectional views illustrating light source apparatuses 1 and 2 according to outline of the first embodiment. As illustrated in FIG. 1 and FIG. 2, each of the light source apparatuses 1 and 2 includes a target holding portion 10 and a temperature adjusting unit 20. Each of the light source apparatuses 1 and 2 may further include a forming unit 50 and an output optical system 60. The target holding portion 10 includes a cylindrical portion 11 and a holding surface 15. The cylindrical portion 11 includes a portion in a cylindrical shape. The holding surface 15 holds a target member TM. The target holding portion 10 holds the target member TM on the holding surface 15 that rotates around a rotational axis R. For example, the target holding portion 10 may hold the target member TM on the holding surface 15 by centrifugal force by rotating around the rotational axis R. The rotational axis R may coincide with a central axis of the cylindrical portion 11. The forming unit 50 forms plasma PZ by irradiating the target member TM with excitation light LR. The output optical system 60 causes light L0 generated from the plasma PZ to be output from the light source apparatuses 1 and 2.

In the light source apparatus 1 in FIG. 1, the holding surface 15 includes an inner peripheral surface of the cylindrical portion 11. Specifically, for example, the target holding portion 10 includes a crucible that rotates around the rotational axis R. The holding surface 15 includes an inner peripheral surface of the crucible. The cylindrical portion 11 includes a portion in a cylindrical shape. In the cylindrical portion 11, one side in a direction of the rotational axis R is open. A bottom portion 12 may be arranged so as to close the other side in the direction of the rotational axis R, of the cylindrical portion 11, or the bottom portion 12 does not have to be arranged. In a case where the bottom portion 12 is arranged, the bottom portion 12 includes a first surface 12a and a second surface 12b. The second surface 12b is a surface opposite to the first surface 12a. The first surface 12a is a surface on the one side, of the bottom portion 12. The second surface 12b is a surface on the other side, of the bottom portion 12. The target holding portion 10 may hold the molten liquid target member TM on the inner peripheral surface of the rotating crucible by centrifugal force.

In the light source apparatus 2 in FIG. 2, the holding surface 15 includes an outer peripheral surface of the cylindrical portion 11. Specifically, for example, the target holding portion 10 includes a drum that rotates around the rotational axis R. The holding surface 15 includes an outer peripheral surface of the drum. The target holding portion 10 may hold the solid target member TM solidified on the outer peripheral surface, on the outer peripheral surface of the rotating drum.

Here, for explanatory convenience of the light source apparatuses 1 and 2, an XYZ orthogonal coordinate system will be introduced. For example, the rotational axis R of the target holding portion 10 is set as a Z axis direction. The Z axis direction may be set as a vertical direction, that is, a gravity direction. Then, a +Z axis direction may be set as upward in the gravity direction, and a −Z axis direction may be set as downward in the gravity direction. Note that the +Z axis direction may be set as downward in the gravity direction, and the −Z axis direction may be set as upward in the gravity direction. Further, the Z axis direction may be set as a horizontal direction orthogonal to the gravity direction or may be set as a direction inclined from the gravity direction.

Here, upward and downward are used to have meaning including not only strictly upward and downward in the gravity direction but also directions inclined due to a manufacturing error in measurement of upward and downward and a manufacturing error in manufacturing of the light source apparatuses 1 and 2, and the like. The upward and the downward having such meaning will be referred to as substantially upward and substantially downward. Note that substantially upward and substantially downward may be simply referred to as upward and downward.

Further, one direction in a direction of the rotational axis R will be referred to as one side, and a direction opposite to the one direction will be referred to as the other side. In a case where the rotational axis R is parallel to the Z axis direction, the +Z axis direction is, for example, the one side, and the −Z axis direction is the other side. Note that the +Z axis direction may be the other side, and the −Z axis direction may be the one side.

The temperature adjusting unit 20 is arranged to face the target holding portion 10. The temperature adjusting unit 20 adjusts a temperature of the cylindrical portion 11. The temperature adjusting unit 20 includes an upstanding wall portion 21. The upstanding wall portion 21 is arranged to face the cylindrical portion 11. For example, the upstanding wall portion 21 faces the cylindrical portion 11 via a gap. The upstanding wall portion 21 faces at least part of the cylindrical portion 11. For example, the upstanding wall portion 21 faces at least part in the direction of the rotational axis R, of the cylindrical portion 11. In other words, the upstanding wall portion 21 may face at least part in the Z axis direction, of the cylindrical portion 11. Specifically, for example, the upstanding wall portion 21 may face a portion on the −Z axis direction side, of the cylindrical portion 11. The upstanding wall portion 21 can adjust the temperature of the target holding portion 10 via the facing cylindrical portion 11.

In the light source apparatuses 1 and 2 in FIG. 1 and FIG. 2, the upstanding wall portion 21 is arranged to face the outer peripheral surface of the cylindrical portion 11.

In the light source apparatuses 1 and 2 in FIG. 1 and FIG. 2, the temperature adjusting unit 20 may include a cooling unit. For example, a temperature of the upstanding wall portion 21 may be maintained at a temperature lower than a temperature of the cylindrical portion 11. Thus, the upstanding wall portion 21 functions as the cooling unit. By this means, the upstanding wall portion 21 cools the cylindrical portion 11. For example, the upstanding wall portion 21 may be connected to a heatsink such as a member through which a refrigerant such as cooling water and cold air flows and a member to which a cooling apparatus such as a Peltier element is attached.

Note that the temperature adjusting unit 20 of each of the light source apparatuses 1 and 2 in FIG. 1 and FIG. 2 may further include a heating unit. For example, the upstanding wall portion 21 may function as the heating unit. For example, the temperature of the upstanding wall portion 21 may be maintained at a temperature higher than the temperature of the cylindrical portion 11. Thus, the upstanding wall portion 21 functions as the heating unit. By this means, the upstanding wall portion 21 heats the cylindrical portion 11. For example, the upstanding wall portion 21 may be connected to a member through which a heating medium such as hot water and hot air flows, a member to which a heating apparatus such as a heater is attached, or the like.

The upstanding wall portion 21 may intersect with a vertical line 16 that is orthogonal to the rotational axis R and passes through a point at which the plasma PZ formed from the target member TM is formed. The point at which the plasma PZ is formed is a point at which a temperature difference from the circumference is the largest. Specifically, for example, a temperature of the point at which the plasma PZ is formed is the highest. Thus, by employing a configuration in which the upstanding wall portion 21 passes through the vertical line 16, the upstanding wall portion 21 can face the point at which the plasma PZ is formed. This makes it possible to alleviate a temperature gradient caused in the target holding portion 10.

The cylindrical portion 11 includes a first cylinder end portion 11a that is an end portion on the one side in the direction of the rotational axis R, and a second cylinder end portion 11b that is an end portion on the other side. The upstanding wall portion 21 includes a first upstanding wall end portion 21a that is an end portion on the one side in the direction of the rotational axis R, and a second upstanding wall end portion 21b that is an end portion on the other side. The first upstanding wall end portion 21a is located relative to the one side relative to the second cylinder end portion 11b. Further, the first upstanding wall end portion 21a is located on the other side relative to the first cylinder end portion 11a. In other words, the first upstanding wall end portion 21a is located between the first cylinder end portion 11a and the second cylinder end portion 11b in the Z axis direction. By this means, the upstanding wall portion 21 faces at least part of the cylindrical portion 11.

The upstanding wall portion 21 includes a facing surface 21c and an opposite surface 21d. The facing surface 21c is a surface facing the cylindrical portion 11. The opposite surface 21d is a surface opposite to the facing surface 21c. The facing surface 21c of the upstanding wall portion 21 may be referred to as an upstanding facing surface, and the opposite surface 21d of the upstanding wall portion 21 may be referred to as an upstanding wall opposite surface.

In the light source apparatuses 1 and 2 in FIG. 1 and FIG. 2, the facing surface 21c faces the outer peripheral surface of the cylindrical portion 11. Specifically, the facing surface 21c faces the outer peripheral surface of the cylindrical portion 11 via a gap.

The upstanding wall portion 21 may be formed in an annular shape over the entire circumference along the rotation direction of the rotational axis R. In this case, in FIG. 2, a hole, or the like, may be formed at a portion through which the excitation light LR and the light L0 pass. Further, the temperature adjusting unit 20 may include a plurality of upstanding wall portions 21. The plurality of upstanding wall portions 21 may be arranged in an annular shape along the rotation direction of the rotational axis R.

At least one of the cylindrical portion 11 and the upstanding wall portion 21 may be coated with a material having a predetermined radiation factor. The predetermined radiation factor may be substantially the same as a radiation factor of the target member TM. For example, at least one of the cylindrical portion 11 and the upstanding wall portion 21 may be coated with the target member TM or a substance that is the same as the target member TM. By this means, a temperature adjustment effect of the temperature adjusting unit 20 can be made substantially equal regardless of, in a case where the target member TM is adhered to a space between the cylindrical portion 11 and the upstanding wall portion 21, an amount of the adhesion. Further, the temperature adjustment effect of the temperature adjusting unit 20 in a case where the target member TM is adhered to the space between the cylindrical portion 11 and the upstanding wall portion 21 can be made substantially equal to the temperature adjustment effect in a case where the target member TM is not adhered to the space between the cylindrical portion 11 and the upstanding wall portion 21.

According to the present embodiment, the upstanding wall portion 21 faces the cylindrical portion 11 so as to cover at least part of the cylindrical portion 11. Thus, the temperature of the cylindrical portion 11 is adjusted to a predetermined temperature by radiation from the upstanding wall portion 21. By this means, the temperature of the target holding portion 10 can be appropriately adjusted. It is therefore possible to reduce deformation of the target holding portion 10.

### Details of First Embodiment

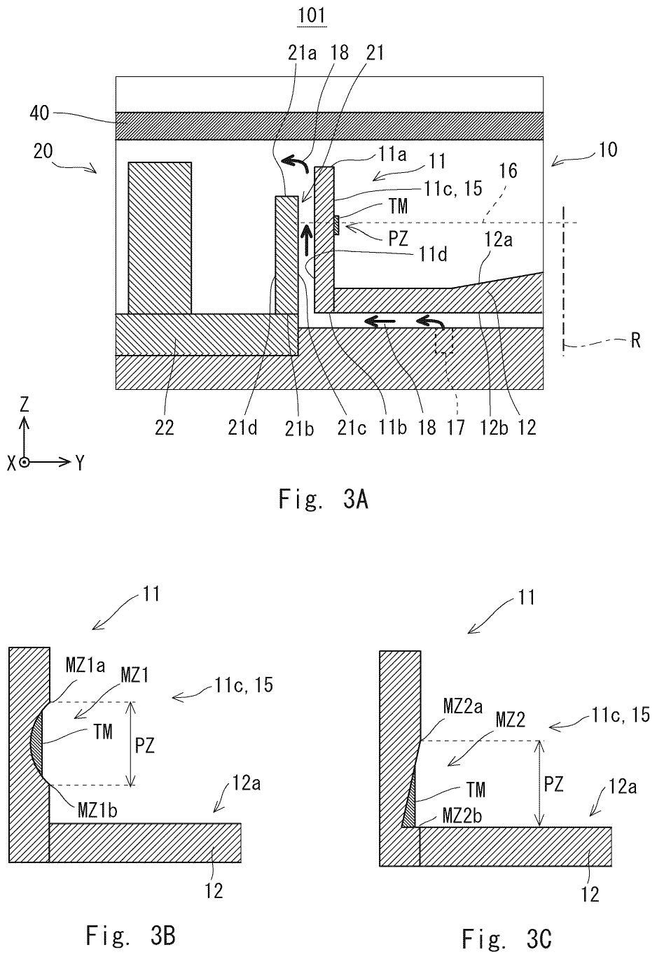

A light source apparatus 101 according to the first embodiment will be described. In the light source apparatus 101 of the present embodiment, the target holding portion 10 includes a crucible. The holding surface 15 includes the inner peripheral surface of the cylindrical portion 11. The temperature adjusting unit 20 includes a cooling unit. The one side is upward in the gravity direction. FIG. 3A is a cross-sectional view illustrating the light source apparatus 101 according to the first embodiment. As illustrated in FIG. 3A, the light source apparatus 101 includes the target holding portion 10 and the temperature adjusting unit 20. The target holding portion 10 includes a bottom portion 12 in addition to the cylindrical portion 11. The temperature adjusting unit 20 includes the upstanding wall portion 21 that functions as the cooling unit connected to the heatsink, or the like. The temperature adjusting unit 20 may further include a heat transfer unit 22 that transfers heat. The upstanding wall portion 21 may be connected to the heatsink, or the like, via the heat transfer unit 22. In FIG. 3A, the forming unit 50 and the output optical system 60 are omitted.

The bottom portion 12 has, for example, a plate shape and includes the first surface 12a facing the one side and the second surface 12b facing the other side. The bottom portion 12 is fitted into the second cylinder end portion 11b so as to close the opening on the other side of the cylindrical portion 11. On the other hand, the one side of the cylindrical portion 11 is open. In the target holding portion 10, an inner peripheral surface 11c of the cylindrical portion 11 is the holding surface 15. An outer peripheral surface 11d of the cylindrical portion 11 faces the upstanding wall portion 21. The outer peripheral surface 11d facing the upstanding wall portion 21 may be referred to as a facing surface, and the inner peripheral surface 11c on the opposite side of the facing surface may be referred to as an opposite surface. Further, the facing surface of the cylindrical portion 11 (the outer peripheral surface 11d in each disclosed embodiment) may be referred to as a cylinder facing surface, and the opposite surface of the cylindrical portion 11 (the inner peripheral surface 11c in each disclosed embodiment) may be referred to as a cylinder opposite surface.

The first upstanding wall end portion 21a of the upstanding wall portion 21 is located on the one side (for example, the +Z axis direction) relative to the second cylinder end portion 11b. This can secure that the upstanding wall portion 21 faces at least part of the cylindrical portion 11. Thus, the upstanding wall portion 21 can adjust the temperature of the target holding portion 10. The second upstanding wall end portion 21b of the upstanding wall portion 21 may match the second cylinder end portion 11b in the Z axis direction. Note that the second upstanding wall end portion 21b of the upstanding wall portion 21 may be either on the one side (+Z axis direction) or on the other side (−Z axis direction) relative to the second cylinder end portion 11b in the Z axis direction. The second upstanding wall end portion 21b of the upstanding wall portion 21 may be connected to the heat transfer unit 22. This makes it possible to maintain the temperature of the upstanding wall portion 21 at a predetermined temperature.

The upstanding wall portion 21 may intersect with the vertical line 16 that is orthogonal to the rotational axis R and passes through a point at which the plasma PZ formed from the target member TM is formed. In other words, the first upstanding wall end portion 21a may be located on the one side relative to the plasma PZ, and the second upstanding wall end portion 21b may be located on the other side relative to the plasma PZ. By this means, the upstanding wall portion 21 faces a portion that is put into a high-temperature state, of the cylindrical portion 11, so that it is possible to effectively adjust the temperature.

FIG. 3B and FIG. 3C illustrate some modifications of the holding surface 15. As illustrated in FIG. 3B and FIG. 3C, a groove portion MZ1 and a groove portion MZ2 are formed on the holding surface 15 in such a manner that a distance from the holding surface 15 to the rotational axis R becomes larger. In a case where the groove portion MZ1 is formed along a circumference of the holding surface 15 as illustrated in FIG. 3B, the point at which the plasma PZ is formed may be located in a height range from an end portion MZ1a on the one side in the Z axis direction, of the groove portion MZ1, to an end portion MZ1b on the other side. The end portion MZ1b on the other side, of the groove portion MZ1, is on the one side in the Z axis direction relative to a contact point of the cylindrical portion 11 and the first surface 12a of the bottom portion 12. Further, in a case where the groove portion MZ2 is formed along the circumference of the holding surface 15 as illustrated in FIG. 3C, the point at which the plasma PZ is formed may be located in a height range from an end portion MZ2a on the one side in the Z axis direction, of the groove portion MZ2, to an end portion MZ2b on the other side. The end portion MZ2b on the other side, of the groove portion MZ2, is located at substantially the same position in the Z axis direction as the contact point of the cylindrical portion 11 and the first surface 12a of the bottom portion 12. In the example in FIG. 3B, the first upstanding wall end portion 21a may be set in the Z axis direction on the other side relative to the end portion MZ1b on the other side, of the groove portion MZ1. Further, the first upstanding wall end portion 21a may be set in the Z axis direction on the other side relative to the end portion MZ1a on the one side, of the groove portion MZ1. Alternatively, the first upstanding wall end portion 21a may be set in the Z axis direction on the one side relative to the end portion MZ1a on the one side, of the groove portion MZ1. In the example in FIG. 3C, the first upstanding wall end portion 21 a may be set in the Z axis direction on the one side relative to the end portion MZ2b on the other side, of the groove portion MZ2. Further, the first upstanding wall end portion 21a may be set in the Z axis direction on the other side relative to the end portion MZ2a on the one side, of the groove portion MZ2. Alternatively, the first upstanding wall end portion 21a may be set in the Z axis direction on the one side relative to the end portion MZ2a on the one side, of the groove portion MZ2. Note that the upstanding wall portion 21 does not necessarily have to include a portion facing the plasma PZ as long as the upstanding wall portion 21 faces at least part of the cylindrical portion 11.

The first upstanding wall end portion 21a of the upstanding wall portion 21 is located on the other side (−Z axis direction) relative to the first cylinder end portion 11a. There is a case where debris may occur if the target member TM is irradiated with the excitation light LR. The debris may move beyond the first cylinder end portion 11a from the inside of the cylindrical portion 11 and reach the outside of the target holding portion 10. Further, droplets of a liquid spattered from the target member TM may move beyond the first cylinder end portion 11a from the inside of the cylindrical portion 11 and reach the outside of the target holding portion 10. In a case where the upstanding wall portion 21 functions as a cooling unit, if the debris and droplets that have moved beyond the first cylinder end portion 11a come into contact with the upstanding wall portion 21, the debris and droplets are solidified on the upstanding wall portion 21. As a result, the grown solidified substance may come into contact with the target holding portion 10 and hinder rotation of the target holding portion 10.

In the present embodiment, the first upstanding wall end portion 21a of the upstanding wall portion 21 is located on the other side relative to the first cylinder end portion 11a, and thus, it is possible to prevent the debris and droplets that have moved beyond the first cylinder end portion 11a from directly colliding with the upstanding wall portion 21.

The light source apparatus 101 may further include a cover 40 in addition to the target holding portion 10, the temperature adjusting unit 20, the forming unit 50, and the output optical system 60. An interval between the cover 40 and the cylindrical portion 11 is narrower than an interval between the cover 40 and the upstanding wall portion 21.

A temperature of the cover 40 may be made equal to or higher than a melting point of the target member TM. As a result of such a configuration being employed, it is possible to prevent the debris and droplets that have moved beyond the first cylinder end portion 11a from being solidified. The temperature of the cover 40 may be made equal to or higher than the melting point of the target member TM by radiation heat of the target member TM.

The light source apparatus 101 may further include an introduction unit 17. The introduction unit 17, for example, ejects gas 18 to the second surface 12b of the bottom portion 12 of the target holding portion 10. The gas 18 may include inert gas such as, for example, nitrogen, argon, and helium. Further, the gas 18 may include gas having high thermal conductivity such as hydrogen and helium. The gas 18 that has introduced from the introduction unit 17 to the second surface 12b of the bottom portion 12 passes through between the cylindrical portion 11 and the upstanding wall portion 21 and is discharged from between the cylindrical portion 11 and the first upstanding wall end portion 21a. As a result of such a configuration being employed, it is possible to prevent the debris and droplets that have moved beyond the first cylinder end portion 11a from colliding with the upstanding wall portion 21.

In the target holding portion 10, the bottom portion 12 may include a portion having a thickness that becomes thicker in the direction of the rotational axis R (Z axis direction) toward the rotational axis R. Specifically, the thickness of the bottom portion 12 may become gradually thicker toward the rotational axis R. This makes it possible to reduce deformation of the target holding portion 10 and improve stability of rotation of the target holding portion 10.

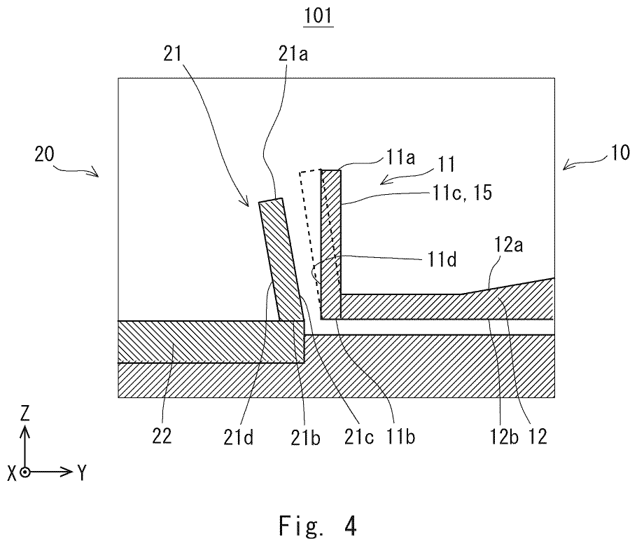

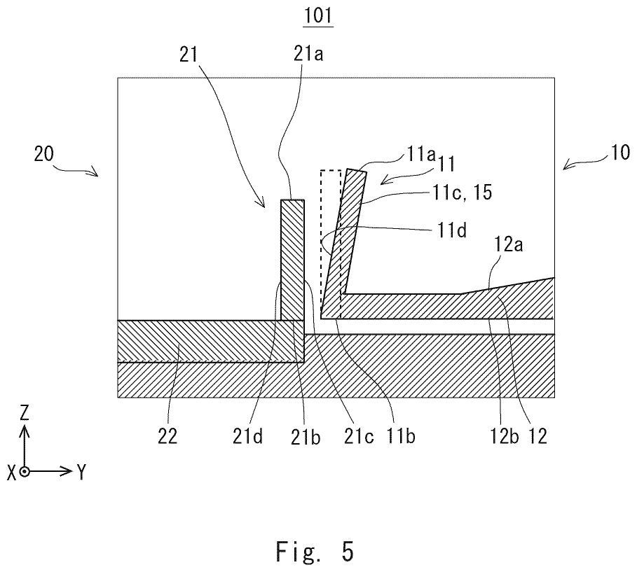

FIG. 4 and FIG. 5 are cross-sectional views illustrating the target holding portion 10 and the upstanding wall portion 21 in the light source apparatus 101 according to the first embodiment. As illustrated in FIG. 4, as a result of the target holding portion 10 rotating at a high speed, the first cylinder end portion 11a in the cylindrical portion 11 may deform so as to bend outward by centrifugal force. As a result of this, there is a possibility that the cylindrical portion 11 may come into contact with the upstanding wall portion 21 or a position at which the plasma PZ occurs may change and thus operation of the light source apparatus 101 may become unstable.

Thus, a gap between the cylindrical portion 11 and the upstanding wall portion 21 may include a portion that becomes wider as it approaches the one side. For example, the facing surface 21c facing the cylindrical portion 11 in the upstanding wall portion 21 may include a portion that is inclined in a direction farther away from the cylindrical portion 11 as it approaches the one side. Note that in a case where the facing surface 21c includes a portion that is inclined in a direction farther away from the cylindrical portion 11 as it approaches the one side, the opposite surface 21d may be made parallel to the facing surface 21c or may be made parallel to, for example, the rotational axis R, other than may be made parallel to the facing surface 21c. In this case, the upstanding wall portion 21 may have a trapezoidal cross-sectional shape.

Further, as illustrated in FIG. 5, the outer peripheral surface 11d facing the upstanding wall portion 21, of the cylindrical portion 11 may include in advance, a portion that is inclined in a direction farther away from the upstanding wall portion 21 as it approaches the one side in view of the first cylinder end portion 11a deforming to bend outward by centrifugal force. Note that in a case where the outer peripheral surface 11d includes a portion that is inclined in a direction farther away from the upstanding wall portion 21 as it approaches the one side, the inner peripheral surface 11c may be made parallel to the outer peripheral surface 11d or may be made parallel to, for example, the rotational axis R, other than may be made parallel to the outer peripheral surface 11d. In this case, the cylindrical portion 11 may have a trapezoidal cross-sectional shape.

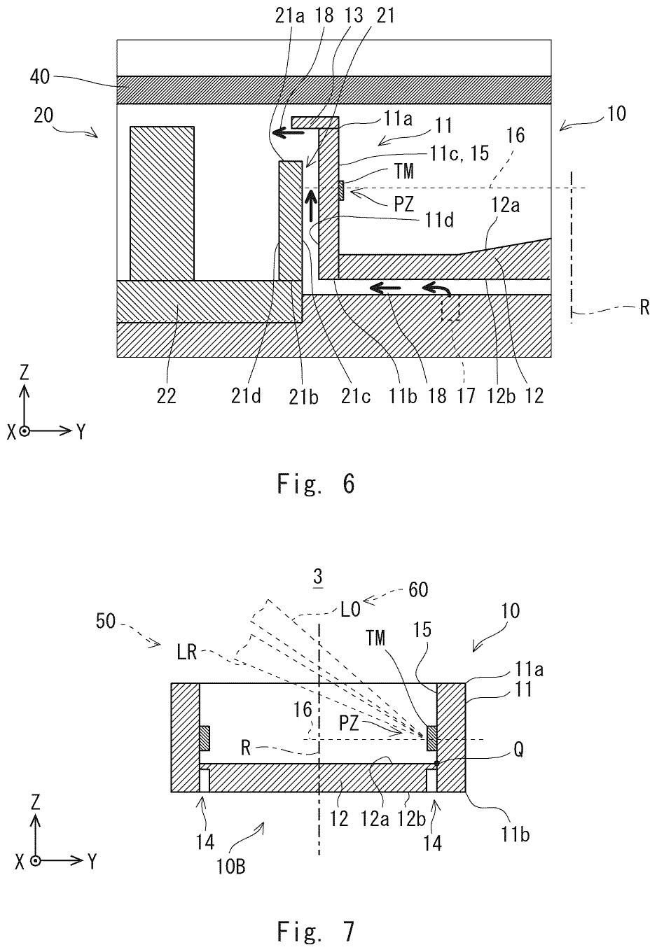

FIG. 6 is a cross-sectional view illustrating a light source apparatus 101a according to a modification of the first embodiment. As illustrated in FIG. 6, in the light source apparatus 101a, the target holding portion 10 may further include a flange portion 13. The flange portion 13 is arranged on the one side of the cylindrical portion 11. Specifically, the flange portion 13 is attached to the first cylinder end portion 11a. The flange portion 13 may include a portion that covers at least part of the first upstanding wall end portion 21a.

The flange portion 13 includes a portion that covers at least part of the first upstanding wall end portion 21a, so that it is possible to prevent the debris and droplets that have moved beyond the first cylinder end portion 11a from directly colliding with the upstanding wall portion 21. Further, the flange portion 13 causes the gas 18 discharged from between the cylindrical portion 11 and the first upstanding wall end portion 21a to be ejected in a direction away from the rotational axis R. It is therefore possible to prevent the debris and droplets that have moved beyond the first cylinder end portion 11a from directly colliding with the upstanding wall portion 21.

Effects of the present embodiment will be described next. The light source apparatus 101 of the present embodiment includes the temperature adjusting unit 20 including the upstanding wall portion 21. It is therefore possible to appropriately adjust the temperature of the target holding portion 10 and prevent deformation of the target holding portion 10. By causing the upstanding wall portion 21 to intersect with the vertical line 16 that passes through the point at which the plasma PZ is formed, it is possible to further appropriately adjust the temperature of the target holding portion 10.

### Outline of Second Embodiment

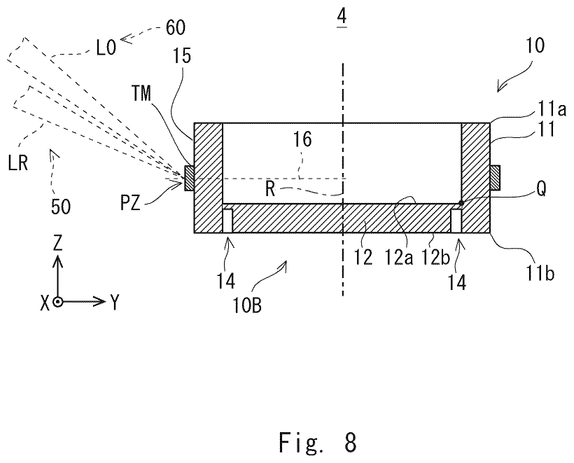

FIG. 7 and FIG. 8 are cross-sectional views illustrating light source apparatuses 3 and 4 according to outline of a second embodiment. As illustrated in FIG. 7 and FIG. 8, each of the light source apparatuses 3 and 4 includes the target holding portion 10. Each of the light source apparatuses 3 and 4 may further include the forming unit 50 and the output optical system 60.

The forming unit 50 forms the plasma PZ by irradiating the target member TM with the excitation light LR. The output optical system 60 causes the light L0 generated from the plasma PZ to be output from the light source apparatuses 3 and 4.

The target holding portion 10 includes the cylindrical portion 11, the bottom portion 12, and the holding surface 15. The cylindrical portion 11 includes a portion in a cylindrical shape. In the cylindrical portion 11, the one side in the direction of the rotational axis R is open. The bottom portion 12 is arranged so as to close the other side of the cylindrical portion 11 in the direction of the rotational axis R. The bottom portion 12 includes the first surface 12a and the second surface 12b. The second surface 12b is a surface opposite to the first surface 12a. The first surface 12a is a surface on the one side, of the bottom portion 12. The second surface 12b is a surface on the other side, of the bottom portion 12.

The holding surface 15 holds the target member TM. The target holding portion 10 holds the target member TM on the holding surface 15 that rotates around the rotational axis R. For example, the target holding portion 10 may hold the target member TM on the holding surface 15 by centrifugal force by rotating around the rotational axis R. A bottom surface 10B on the other side, of the target holding portion 10 includes a groove 14 extending to the one side. The bottom surface 10B includes the second cylinder end portion 11b and the second surface 12b. The groove 14 may be formed in a circular shape over the entire circumference along the rotation direction of the rotational axis R on the bottom surface 10B of the target holding portion 10.

A virtual groove 14 in a case where the groove 14 is virtually extended to the one side may reach the vicinity of a contact point Q of the cylindrical portion 11 and the first surface 12a of the bottom portion 12 and, for example, the virtual groove 14 may contact the contact point Q or may include the contact point Q. By this means, a portion (which may be referred to as a pivot point or a hinge portion) between the first surface 12a of the bottom portion 12 and the bottom of the groove 14 (one side end portion of the groove 14) functions as a hinge (pivot point) by centrifugal force of the cylindrical portion 11, and a deformation range of the cylindrical portion 11 can be easily predicted or a movement range by deformation of the cylindrical portion 11 can be reduced.

According to the present embodiment, the bottom surface 10B on the other side, of the target holding portion 10 includes the groove 14 that extends to the one side, so that mass of the cylindrical portion 11 can be dispersed on the one side and on the other side using a region from the bottom of the groove 14 to the first surface 12a of the bottom portion 12 as a pivot point. In other words, for moment around the pivot point based on the centrifugal force acting on the target holding portion 10 by rotation around the rotational axis R, by making the moment based on the centrifugal force acting on the other side of the pivot point greater than the moment around the pivot point based on the centrifugal force acting on the one side of the pivot point, force that deforms the cylindrical portion 11 to the rotational axis R side with respect to the one side can be exerted. By this means, change in position by deformation of the cylindrical portion 11 to bend outward of the rotational axis R described based on FIG. 4 and FIG. 5 in the first embodiment can be cancelled out.

Further, according to the present embodiment, the hinge portion formed by the groove 14 functions as a heat resistor of heat propagating to the rotational axis R, so that it is possible to prevent heat from propagating to the rotational axis R. This can prevent influence on a lubricant around a shaft located at the rotational axis R.

### Details of Second Embodiment

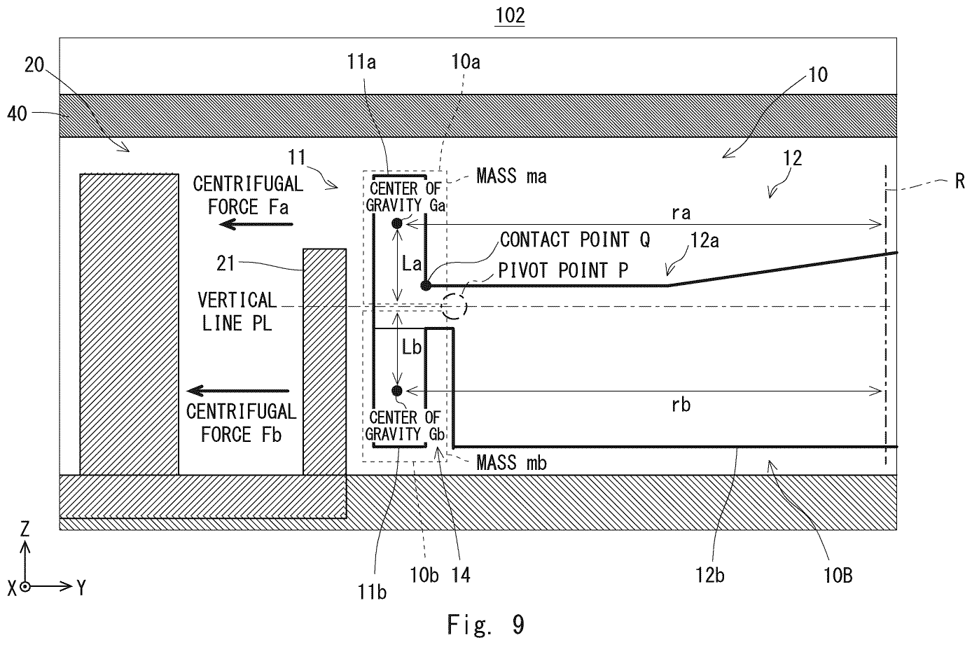

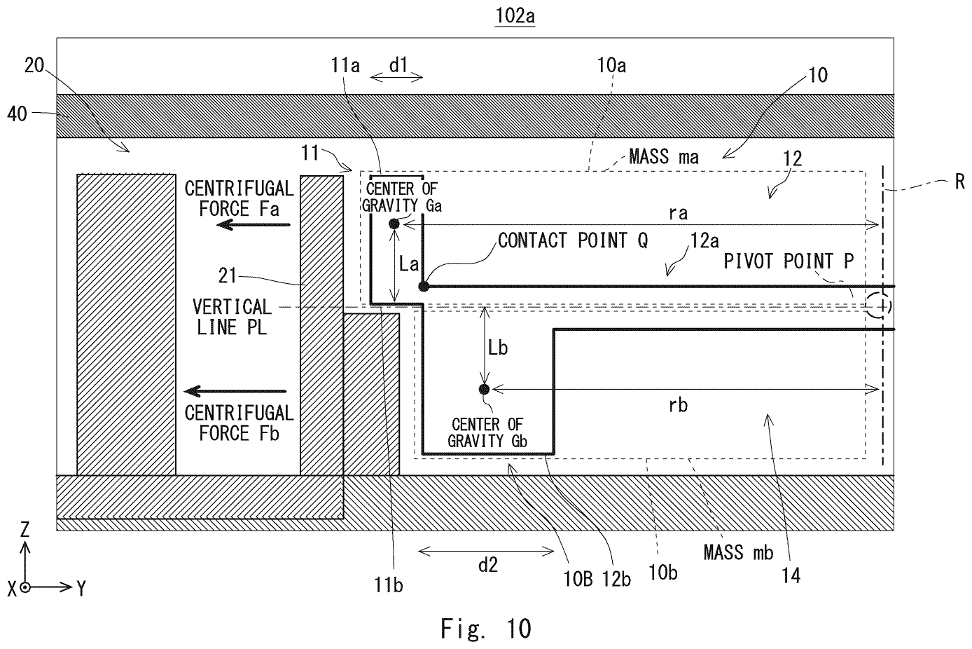

The light source apparatus according to the second embodiment will be described next. In the light source apparatus of the present embodiment, the target holding portion 10 includes the groove 14 on the bottom surface 10B. FIG. 9 is a cross-sectional view illustrating the light source apparatus 102 according to the second embodiment. In FIG. 9, hatching of the target holding portion 10 is omitted and only outline is indicated to prevent the drawing from becoming complicated. As illustrated in FIG. 9, the light source apparatus 102 includes the target holding portion 10. The target holding portion 10 includes the cylindrical portion 11 and the bottom portion 12. The light source apparatus 102 may further include the temperature adjusting unit 20. The temperature adjusting unit 20 includes the upstanding wall portion 21 that functions as a cooling unit such as a heatsink. In FIG. 9, the forming unit 50 and the output optical system 60 are omitted.

In the present embodiment, the bottom surface 10B on the other side, of the target holding portion 10, includes the groove 14 that extends to the one side. The bottom surface 10B of the target holding portion 10 includes the second cylinder end portion 11b of the cylindrical portion 11 and the second surface 12b of the bottom portion 12. For example, the groove 14 is formed on the second surface 12b of the bottom portion 12. While the groove 14 is formed around the second surface 12b, a position where the groove 14 is formed is not limited to this. The groove 14 may be formed at the second cylinder end portion 11b or may be formed in the vicinity of the rotational axis R on the second surface 12b of the bottom portion 12 if the position is on the bottom surface 10B of the target holding portion 10. A region from the first surface 12a of the bottom portion 12 to the bottom of the groove 14 (one side end portion of the groove 14) will be referred to as a hinge portion, and a point included in the region will be referred to as a pivot point P.

The position of the pivot point P depends on physical design, or the like of the bottom portion 12, but, as an example, the pivot point P may be set at a point located at an intersecting point (line of intersection) of an intermediate surface between the first surface 12a of the bottom portion 12 and the bottom of the groove 14 and a surface obtained by extending a side surface on the rotational axis R side, of the groove 14. Note that while the pivot point P will be described as a point to provide description using a cross-section of the target holding portion 10 as an example, in a case where the groove 14 is formed, for example, in an annular shape to have a range along the circumference, the pivot point P can be assumed to be located at each of the cross-sections along the circumference of the groove 14.

In a case where a plane including the rotational axis R and the pivot point P is set as a surface having a minute thickness, a region on the rotational axis R outer side of the pivot point P and on the one side of the pivot point P in the target holding portion 10 is set as a first region 10a. Further, in a case where the plane including the rotational axis R and the pivot point P is set as a surface having a minute thickness, a region on the rotational axis R outer side of the pivot point P and on the other side of the pivot point P in the target holding portion 10 is set as a second region 10b. The first region 10a includes the first cylinder end portion 11a. There is a case where the first region 10a includes part of the bottom portion 12. The second region 10b includes at least one of part of the bottom portion 12 or the second cylinder end portion 11b. There is a case where the second region 10b does not include the second cylinder end portion 11b as in a modification which will be described later.

In the light source apparatus 102 according to the present embodiment, the groove 14 is formed on the bottom surface 10B on the other side, of the target holding portion 10, and, by the configuration which will be described later, moment Ma around the pivot point P based on centrifugal force Fa applied to the first region 10a in a case where the target holding portion 10 rotates around the rotational axis R is smaller than moment Mb around the pivot point P based on centrifugal force Fb applied to the second region 10b.

In a case where the target holding portion 10 rotates around the rotational axis R at a rotation speed ω, the centrifugal force Fa applied to the first region 10a and the centrifugal force Fb applied to the second region 10b are respectively expressed as in the following expression (1) and expression (2).

$$Fa = ma \times ω \hat{} 2 \times ra \qquad ( 1 )$$

$$Fb = mb \times ω \hat{} 2 \times rb \qquad ( 2 )$$

Here, ma is mass of the first region 10a, mb is mass of the second region 10b, ra is a distance from the rotational axis R to the center of gravity Ga of the first region 10a, and rb is a distance from the rotational axis R to the center of gravity Gb of the second region 10b.

Further, the moment Ma around the pivot point P based on the centrifugal force Fa applied to the first region 10a and the moment Mb around the pivot point P based on the centrifugal force Fb applied to the second region 10b are respectively expressed as in the following expression (3) and expression (4).

$$Ma = Fa \times La = ma \times ω \hat{} 2 \times ra \times La \qquad ( 3 )$$

$$Mb = Fb \times La = m b \times ω \hat{} 2 \times rb \times Lb \qquad ( 4 )$$

Here, La is a distance from a vertical line PL of the rotational axis R that passes through the pivot point P to the center of gravity Ga of the first region 10a, and Lb is a distance from the vertical line PL to the center of gravity Gb of the second region 10b. Note that Ma and Mb are used to represent magnitudes of the moment.

In the two expressions indicating Ma and Mb, ω is a common value. Thus, by setting the mass and the positions of the centers of gravity of the first region 10a and the second region 10b, Ma<Mb can be satisfied. In other words, the mass and the positions of the centers of gravity of the first region 10a and the second region 10b are set such that ma×ra×La becomes smaller than mb×rb×Lb. In the target holding portion 10 according to the present embodiment, mb and ma are set such that mb >ma is satisfied by constituting a portion on the other side relative to the bottom portion of the groove 14 of the cylindrical portion 11 to have higher density than a portion on the one side based on La=Lb, and ra=rb. By this means, ma×ra×La is set to be smaller than mb×rb×Lb, and Ma<Mb is satisfied upon rotation around the rotational axis R.

Ma and Mb are respectively moment in reverse directions around the pivot point P, and Ma<Mb, and thus, as a result of the target holding portion 10 rotating around the rotational axis R, a region including the first region 10a and the second region 10b rotates (is inclined) in a direction of Mb around the pivot point P. Then, in accordance with rotation of the region including the first region 10a and the second region 10b in the direction of Mb around the pivot point P, reaction force by material deformation occurs, and at a position at which a sum of Ma and the moment by the reaction force comes into balance with Mb, the rotation of the region including the first region 10a and the second region 10b around the pivot point P is stopped.

Effects of the light source apparatus 102 of the second embodiment will be described. As described above, Ma and Mb are respectively moment in reverse directions around the pivot point P, and Ma<Mb, and thus, the cylindrical portion 11 rotates in the direction of Mb around the pivot point P, and as a result, the first cylinder end portion 11a approaches the rotational axis R. Then, even in a case where the first cylinder end portion 11a deforms to bend outward of the rotational axis R (see FIG. 4 and FIG. 5) as a result of the target holding portion 10 rotating around the rotational axis R, it is possible to prevent contact with the upstanding wall portion 21 and make the position of the plasma PZ close to the position before the first cylinder end portion 11a bends outward. In other words, change in position by deformation of the first cylinder end portion 11a to bend outward of the rotational axis R can be cancelled out by rotation by a difference in moment.

Further, the groove 14 functions as a heat resistor of heat transferred from the cylindrical portion 11 to the rotational axis R. There is a case where the heat of the target member TM propagates to a shaft at which the rotational axis R is located from the cylindrical portion 11. A thickness of the bottom portion 12 at the portion of the groove 14 in the target holding portion 10 is thin, so that it is possible to prevent propagation of heat to the shaft. The shaft is connected to the bottom portion 12 of the target holding portion 10. The shaft is covered with a lubricant such as grease for smooth rotation. There is a possibility that the heat propagating from the cylindrical portion 11 may affect the lubricant and may inhibit rotation of the target holding portion 10. Thus, in the present embodiment, the groove 14 is formed on the bottom surface 10B of the target holding portion 10, so that it is possible to prevent heat from propagating from the cylindrical portion 11 to the rotational axis R. A length of the groove 14 in the direction of the rotational axis R may be longer than a length from the bottom of the groove 14 to the first surface 12a. By this means, the effect of heat resistance can be improved.

The bottom surface 10B on the other side, of the target holding portion 10 may include only one groove 14 in a radius direction of the rotational axis R. In this event, a dimension of the bottom of the groove 14 (one side end portion of the groove 14) in the radius direction of the rotational axis R, that is, a width of the groove 14 in the radius direction of the rotational axis R may be smaller than a dimension of the cylindrical portion 11 in the direction of the rotational axis R, that is, a height of the cylindrical portion 11 in the direction of the rotational axis R. For example, the dimension of the bottom of the groove 14 (one side end portion of the groove 14) in the radius direction of the rotational axis R may be smaller than the dimension of the first cylinder end portion 11a in the direction of the rotational axis R. Further, the width of the groove 14 in the radius direction of the rotational axis R may be smaller than the height of the cylindrical portion 11 (distance from the first cylinder end portion 11a to the first surface 12a of the bottom portion 12). Further, the virtual groove 14 in a case where the groove 14 is virtually extended to the one side may reach the vicinity of the contact point Q of the cylindrical portion 11 and the first surface 12a of the bottom portion 12, and, for example, the virtual groove 14 may come into contact with the contact point Q or include the contact point Q. By this means, exertion of the respective functions of the hinge portion and the pivot point P is secured, and the above-described effect can be provided in a more favorable manner. Note that a distance from the bottom of the groove 14 to the first surface 12a of the bottom portion 12 may be set equal to or less than a distance of the width of the groove 14 in the radius direction of the rotational axis R.

The bottom surface 10B on the other side, of the target holding portion 10 may include two or more grooves 14 in the radius direction of the rotational axis R. In this event, for the groove 14 farthest from the rotational axis R among the plurality of grooves 14, a distance from the first surface 12a of the bottom portion 12 to the bottom of the groove 14 (one side end portion of the groove 14) may be made the shortest. By this means, a portion between the first surface 12a of the bottom portion 12 in the outermost groove 14 and the bottom of the groove 14 (one side end portion of the groove 14) functions as a hinge (pivot point P) upon deformation by the centrifugal force of the cylindrical portion 11, so that a deformation range of the cylindrical portion 11 can be easily predicted, and a movement range by deformation of the cylindrical portion 11 can be reduced.

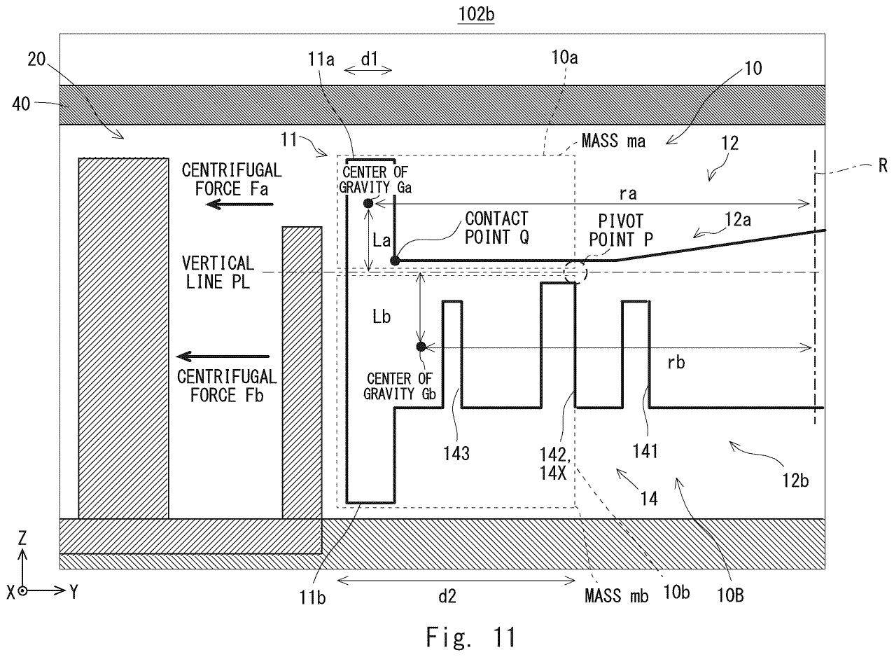

FIG. 10 is a cross-sectional view illustrating a light source apparatus 102a according to a modification of the second embodiment. As illustrated in FIG. 10, in the light source apparatus 102a, the second cylinder end portion 11b is formed on the one side relative to the second surface 12b on the other side, of the bottom portion 12 of the target holding portion 10. On the bottom surface 10B, the groove 14 is formed toward the one side of the bottom surface 10B. As illustrated in FIG. 10, the groove 14 may be formed to reach the rotational axis R. A width d2 of a region on an outer side in the radius direction, of a region where the groove 14 is formed, among the bottom surface 10B is wider than a width d1 in the radius direction, of the cylindrical portion 11.

In the light source apparatus 102a according to the modification of the second embodiment, the first region 10a includes the first cylinder end portion 11a and part of the bottom portion 12. The second region 10b includes part of the bottom portion 12 but does not include the second cylinder end portion 11b. In the light source apparatus 102a according to the modification of the second embodiment, as a result of d2>d1 being satisfied, ma×ra×La is set smaller than mb×rb×Lb, and thus Ma<Mb is satisfied upon rotation around the rotational axis R.

Note that in a case where the groove 14 is formed to include the rotational axis R as in the present modification, the pivot point P may be set as a contact point of an intermediate surface of the first surface 12a of the bottom portion 12 and the groove 14, and the rotational axis R. Alternatively, in a case where the bottom portion 12 includes a portion having a thickness that becomes thicker in the direction of the rotational axis R toward the rotational axis R, an intermediate position between the first surface 12a of the bottom portion 12 at a portion at which a distance between the first surface 12a of the bottom portion 12 and the bottom of the groove 14 is the shortest among the bottom of the groove 14, and the bottom of the groove 14 may be set as the pivot point P.

Also in the present modification, Ma and Mb are respectively moment in reverse directions around the pivot point P, and Ma<Mb is satisfied. Thus, in a similar manner to described above, even in a case where the first cylinder end portion 11a deforms to bend outward of the rotational axis R as a result of the target holding portion 10 rotating around the rotational axis R, it is possible to prevent contact with the upstanding wall portion 21. Further, while the groove 14 may include the rotational axis R in the present modification, also in this case, it is possible to prevent heat from propagating from the cylindrical portion 11 to the rotational axis R by making the width of the groove 14 in the radius direction wider. Other configurations and effects are included in the description of the first and second embodiments and respective modifications.

FIG. 11 is a cross-sectional view illustrating a light source apparatus 102b according to a modification of the second embodiment. As illustrated in FIG. 11, in the light source apparatus 102b, the second cylinder end portion 11b is formed on the other side relative to the bottom surface 10B of the target holding portion 10. On the bottom surface 10B, a plurality of grooves 14 is formed at positions with different distances from the rotational axis R toward the one side of the bottom surface 10B. Here, the plurality of grooves 14 is set as grooves 141, 142, and 143 in ascending order of the distance to the rotational axis R. As an example, the groove 142 is a groove for which a distance from the first surface 12a on the one side, of the bottom portion 12 to the one side end portion of the groove 14 is the shortest.

In a case where the plurality of grooves 14 is formed on the bottom surface 10B toward the one side at positions with different distances from the rotational axis R, the mass ma and the position of the center of gravity Ga of the first region 10a are optionally set assuming the pivot point P as described below. In other words, among the plurality of grooves 14 (the groove 141 to the groove 143), the groove 14 (groove 142) for which the distance from the first surface 12a of the bottom portion 12 to the bottom of the groove 14 (end portion on the one side, of the groove 14) is the shortest is referred to as a dominant groove 14X, a region from the first surface 12a of the bottom portion 12 to the bottom of the dominant groove 14X is referred to as a hinge portion, and a point included in the region is set as the pivot point P. While the position of the pivot point P depends on physical design, or the like, of the bottom portion 12 in a similar manner to described above, as an example, the pivot point P may be located at an intersection of the intermediate surface of the first surface 12a of the bottom portion 12 and the bottom of the dominant groove 14X, and a surface obtained by extending a side surface on the rotational axis R side of the dominant groove 14X. In a case where the dominant groove 14X is formed to include the rotational axis R, a contact point of the first surface 12a of the bottom portion 12 and the bottom of the dominant groove 14X, and the rotational axis R may be set as the pivot point P. Alternatively, in a case where the bottom portion 12 includes a portion having a thickness that becomes thicker in the direction of the rotational axis R toward the rotational axis R, or the like, an intermediate position of the first surface 12a of the bottom portion 12 at a portion at which a distance between the first surface 12a of the bottom portion 12 and the bottom of the dominant groove 14X is the shortest among the bottom of the dominant groove 14X, and the bottom of the dominant groove 14X may be set as the pivot point P.

In the light source apparatus 102b according to the modification of the second embodiment, as a result of at least one of the width d2 of the region on an outer side in the radius direction, of the dominant groove 14X (groove 142) among the bottom surface 10B being made wider than the width d1 in the radius direction of the cylindrical portion 11 or the second cylinder end portion 11b being provided on the other side relative to the second surface 12b on the other side, of the bottom portion 12, ma×ra×La is smaller than mb×rb×Lb, and thus Ma<Mb is satisfied upon rotation around the rotational axis R.

Also in the present modification, Ma and Mb are respectively moment in reverse directions around the pivot point P, and Ma<Mb is satisfied. Thus, in a similar manner to described above, even in a case where the first cylinder end portion 11a deforms to bend outward of the rotational axis R as a result of the target holding portion 10 rotating around the rotational axis R, it is possible to prevent contact with the upstanding wall portion 21. Further, in the present modification, a plurality of grooves 14 is provided, so that it is possible to further improve a function as a heat resistor of heat transferred from the cylindrical portion 11 to the rotational axis R. Still further, as a result of the second cylinder end portion 11b being provided on the other side relative to the second surface 12b on the other side, of the bottom portion 12, a region where the temperature adjusting unit 20 is provided can be increased. Other configurations and effects are included in the description of the first and second embodiments and the respective modifications.

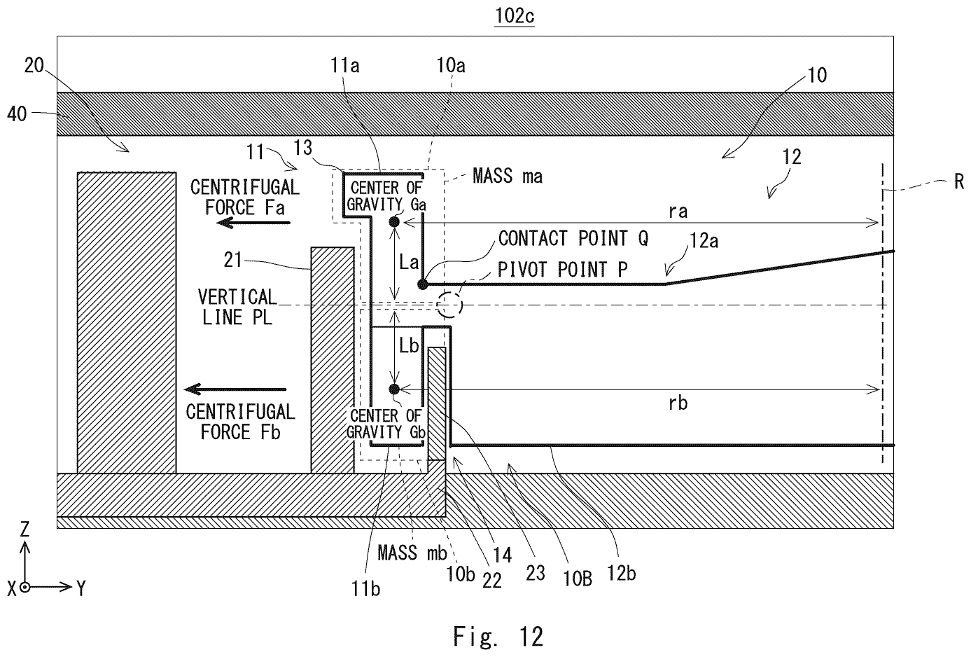

FIG. 12 is a cross-sectional view illustrating a light source apparatus 102c according to a modification of the second embodiment. The target holding portion 10 of the light source apparatus 102c may further include the flange portion 13. The flange portion 13 has effects similar to those of the modification of the first embodiment and can contribute to adjustment of the mass ma.

Further, in the light source apparatus 102c according to the modification of the second embodiment, the light source apparatus 102c may include the temperature adjusting unit 20. Further, the temperature adjusting unit 20 may include an upstanding wall portion 23 in the groove 14. With such a configuration, the temperature adjusting unit 20 of the present modification adjusts the temperature of the target holding portion 10 including the cylindrical portion 11 also from the inside of the groove 14 of the target holding portion 10. Thus, the temperature is adjusted from both sides of the cylindrical portion 11, so that it is possible to further effectively adjust the temperature and prevent deformation of the target holding portion 10. Other configurations and effects are included in the description of the first and second embodiments and the respective modifications.

While the embodiments of the present disclosure have been described above, the present disclosure includes appropriate modifications that do not impair the object and advantages of the present disclosure, and further, is not limited by the above-described embodiments. Further, configurations of the first and second embodiments including outline of the first and second embodiments, and the respective modifications may be combined as appropriate.

The first and second embodiments can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A light source apparatus comprising:
a target holding portion including a cylindrical portion in a cylindrical shape, and a holding surface that holds a target member, the target holding portion holding the target member on the holding surface that rotates around a rotational axis; and
a temperature adjusting unit configured to adjust a temperature of the cylindrical portion,
wherein the temperature adjusting unit includes an upstanding wall portion arranged to face an outer peripheral surface of the cylindrical portion, and
wherein the upstanding wall portion faces at least part of the outer peripheral surface of the cylindrical portion.

2. The light source apparatus according to claim 1, wherein:
the cylindrical portion includes a first cylinder end portion that is an end portion on one side in a direction of the rotational axis, and a second cylinder end portion that is an end portion on the other side,
the upstanding wall portion includes a first upstanding wall end portion that is the end portion on the one side in the direction of the rotational axis, and a second upstanding wall end portion that is the end portion on the other side,
the upstanding wall portion faces the outer peripheral surface of the cylindrical portion via a gap, and
the first upstanding wall end portion is located on the one side relative to the second cylinder end portion and is located on the other side relative to the first cylinder end portion.

3. The light source apparatus according to claim 1, wherein the upstanding wall portion intersects with a vertical line that is orthogonal to the rotational axis and passes through a point at which plasma formed from the target member is formed.

4. The light source apparatus according to claim 1, wherein the upstanding wall portion is formed in an annular shape over the entire circumference along a rotation direction of the rotational axis.

5. The light source apparatus according to claim 1, wherein:
the temperature adjusting unit plurally includes the upstanding wall portion as a plurality of upstanding wall portions, and
the plurality of upstanding wall portions are arranged in an annular shape along a rotation direction of the rotational axis.

6. The light source apparatus according to claim 1, further comprising a cover that covers at least part on one side in the direction of the rotational axis, of the target holding portion,
wherein an interval between the cover and the cylindrical portion is narrower than an interval between the cover and the upstanding wall portion.

7. The light source apparatus according to claim 2, wherein:
the target holding portion further comprises a flange portion arranged on the one side of the cylindrical portion, and
the flange portion includes a portion that covers at least part of the first upstanding wall end portion.

8. The light source apparatus according to claim 2, further comprising an introduction unit that introduces gas discharged from between the cylindrical portion and the first upstanding wall end portion.

9. The light source apparatus according to claim 1, wherein at least one of the cylindrical portion and the upstanding wall portion is coated with a material having a predetermined radiation factor.

10. The light source apparatus according to claim 9, wherein the predetermined radiation factor is substantially the same as a radiation factor of the target member.

11. The light source apparatus according to claim 1, wherein:
the target holding portion further includes a bottom portion arranged to close the other side in the direction of the rotational axis of the cylindrical portion,
the one side in the direction of the rotational axis of the cylindrical portion is open, and
a gap between the cylindrical portion and the upstanding wall portion includes a portion that becomes wider as it approaches the one side.

12. The light source apparatus according to claim 11, wherein an upstanding wall facing surface facing the cylindrical portion, of the upstanding wall portion, includes a portion that is inclined in a direction farther away from the cylindrical portion as it approaches the one side.

13. The light source apparatus according to claim 11, wherein a cylinder facing surface facing the upstanding wall portion, of the cylindrical portion, includes a portion that is inclined in a direction farther away from the upstanding wall portion as it approaches the one side.

14. The light source apparatus according to claim 1, wherein:
the target holding portion further includes a bottom portion that closes the other side in the direction of the rotational axis of the cylindrical portion,
the one side in the direction of the rotational axis of the cylindrical portion is open, and
the bottom portion includes a portion having a thickness that becomes greater in the direction of the rotational axis toward the rotational axis.

15. The light source apparatus according to claim 14, wherein the thickness becomes gradually thicker toward the rotational axis.

16. The light source apparatus according to claim 1, wherein:
the holding surface includes an inner peripheral surface of the cylindrical portion, and
the upstanding wall portion includes a cooling unit that cools the cylindrical portion.

17. The light source apparatus according to claim 1, wherein:
the holding surface includes the outer peripheral surface of the cylindrical portion, and
the upstanding wall portion includes a cooling unit that cools the cylindrical portion.
